(19) United States
(12) Patent Application Publication
(10) Pub. No.: US 2014/0355230 A1
(43) Pub. Date: Dec. 4, 2014

(54) PROTECTION COVER AND ELECTRONIC DEVICE HAVING THE SAME

(71) Applicant: Samsung Electronics Co., Ltd., Gyeonggi-do (KR)

(72) Inventor: Sungyoung Lee, Gyeongsangbuk-do (KR)

(21) Appl. No.: 14/296,309

(22) Filed: Jun. 4, 2014

(30) Foreign Application Priority Data
Jun. 4, 2013 (KR) 10-2013-0064257

(51) Int. Cl. H05K 9/00; H05K 5/02; H05K 5/00

(52) U.S. Cl. CPC H05K 9/0026; H05K 5/0086; H05K 5/02
USPC 361/752; 312/223.1

(57) ABSTRACT

A protection cover configured to protect an electronic device from external impact, includes a rear case where a battery is mounted, and a shield-can made of a metal and coupled to an inner portion of the rear case. The rear case may comprise a first restraint portion configured to restrain the shield-can, and the shield-can may include a second restraint portion corresponding to the first restraint portion. An electronic device includes a front case where a display unit is mounted, a rear case coupled to the front case and including at least one first restraint portion, a printed circuit board positioned between the front case and the rear case, and a shield-can made of a metal and positioned between the printed circuit board and the rear case, the shield-can including at least one second restraint portion corresponding to the at least one first restraint portion.

### CROSS-REFERENCE TO RELATED APPLICATION AND CLAIM OF PRIORITY

The present application is related to and claims priority from and the benefit under 35 U.S.C. §119(a) of Korean Patent Application No. 10-2013-0064257, filed on Jun. 4, 2013, which is hereby incorporated by reference for all purposes as if fully set forth herein.

### TECHNICAL FIELD

The present disclosure relates to an apparatus for protecting an electronic device and an electronic device having the same, and more particularly, an apparatus for protecting an electronic device capable of preventing an electronic device from being damaged, for example, by external impact and an electronic device having the same.

### BACKGROUND

In virtue of recent remarkable development of information communication technologies, semiconductor technologies etc., distribution and use of electronic devices are rapidly increasing and become necessaries of modern people. Considering portability, such electronic devices are being miniaturized, slimmed, made to be gripped, and lightened and provide various functions needed by users.

Recent electronic devices are provided with display devices on the front face thereof. In addition, display devices are enlarged in the recent electronic devices. Such display devices are formed of a glass material and thus, are fragile to external impact. Even though conventional electronic devices include display devices formed with a glass material, the electronic devices are not provided with separate devices for protecting the display devices. Thus, when external impact is applied to such an electronic device due to, for example, falling, the external impact is applied to the display device or the case, the internal elements, etc. of the electronic device intactly without being properly absorbed or dispersed. Thus, recent electronic devices have a problem in that they are fragile to external impact.

### SUMMARY

To address the above-discussed deficiencies, it is a primary object to provide an apparatus for protecting an electronic device that is capable of preventing damage of an electronic device by external impact and an electronic device having the same.

According to an aspect of the present disclosure, a protection cover includes a rear case where a battery is mounted, and a shield-can is made of a metal and coupled to an inner portion of the rear case. The rear case may include a first restraint portion configured to restrain the shield-can, and the shield-can includes a second restraint portion corresponding to the first restraint portion.

According to another aspect of the present disclosure, an electronic device includes a front case where a display unit is mounted, a rear case coupled to the front case and including at least one first restraint portion, a printed circuit board positioned between the front case and the rear case, and a shield-can made of a metal and positioned between the printed circuit board and the rear case. The shield-can includes at least one second restraint portion corresponding to the at least one first restraint portion.

As described above, an apparatus for protecting an electronic device and an electronic device having the same according to the present disclosure may prevent damage of internal components (e.g., a display unit, a battery, etc.) of the electronic device by external impact. In addition, the present disclosure may increase rigidity of an electronic device using a shield-can which is a component which is usually used in such an electronic device without adding a separate component. Due to this, the present disclosure may reduce material costs of the electronic device.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates an external appearance of an electronic device according to an aspect of the present disclosure;

FIG. 2 illustrates an internal configuration of the electronic device according to an aspect of the present disclosure;

FIG. 3 illustrates a shield-can and a rear case in the internal configuration of the electronic device according to an aspect of the present disclosure;

FIG. 4A illustrates a restraint structure according to a first exemplary embodiment of the present disclosure;

FIG. 4B is a cross-section view taken along the line A-A′ shown in FIG. 4A;

FIG. 5A illustrates a restraint structure according to a second exemplary embodiment of the present disclosure;

FIG. 5B is a cross-section view taken along the line B-B′ shown in FIG. 5A;

FIG. 6A illustrates a restraint structure according to a third exemplary embodiment of the present disclosure;

FIG. 6B is a cross-section view taken along the line C-C′ shown in FIG. 6A;

FIG. 7A illustrates a restraint structure according to a fourth exemplary embodiment of the present disclosure;

FIG. 7B is a cross-section view taken along the line D-D′ shown in FIG. 7A;

FIG. 8 illustrates a restraint structure according to a fifth exemplary embodiment of the present disclosure;

FIG. 9 illustrates a restraint structure according to a sixth exemplary embodiment of the present disclosure;

FIG. 10 illustrates a restraint structure according to a seventh exemplary embodiment of the present disclosure; and

FIG. 11 illustrates a restraint structure according to an eighth exemplary embodiment of the present disclosure.

### DETAILED DESCRIPTION

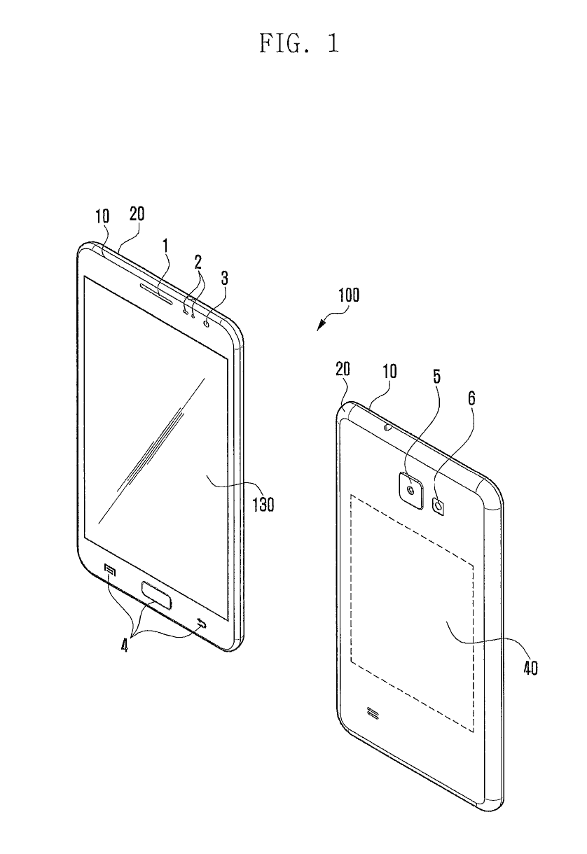

FIGS. 1 through 11, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged electronic devices. Hereinafter, preferred embodiments of the present disclosure will be described in detail with reference to the accompanying drawings. It should be noted that the same elements will be designated by the same reference numerals although they are shown in different drawings. Further, in the following description of the present disclosure, a detailed description of known functions and configurations incorporated herein will be omitted when it may make the subject matter of the present disclosure rather unclear.

Meanwhile, the exemplary embodiments disclosed in the specification and drawings are merely presented to easily describe technical contents of the present disclosure and help the understanding of the present disclosure and are not intended to limit the scope of the present disclosure. It is obvious to those skilled in the art to which the present disclosure pertains that other modified embodiments on the basis of the spirit of the present disclosure besides the embodiments disclosed herein can be carried out.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely. Definitions for certain words and phrases are provided throughout this patent document, those of ordinary skill in the art should understand that in many, if not most instances, such definitions apply to prior, as well as future uses of such defined words and phrases.

In the following detailed description, an electronic device according to an aspect of the present disclosure may be a mobile communication electronic device, a smart phone, a tablet Personnel Computer (PC), a Personal Digital Assistant (PDA), or the like.

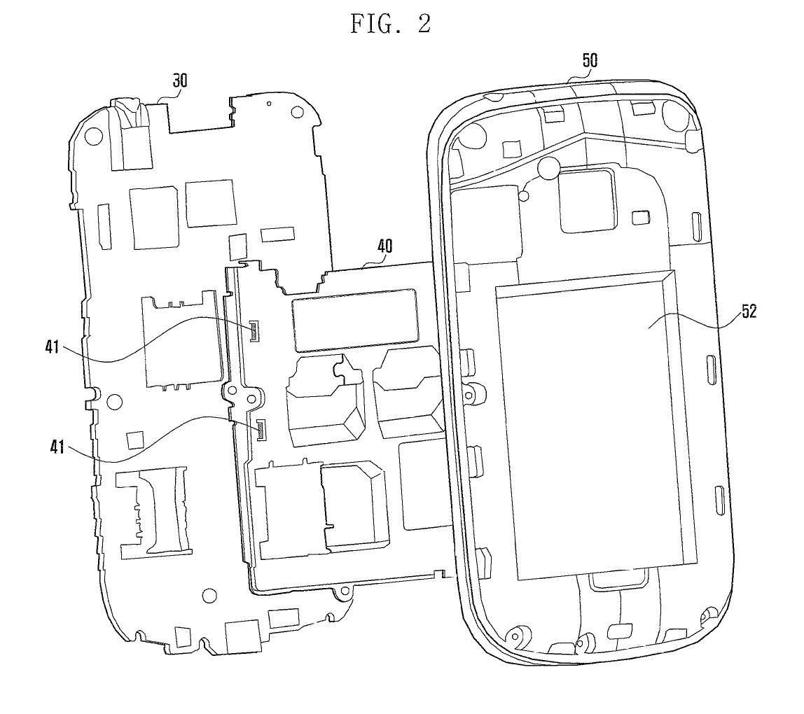

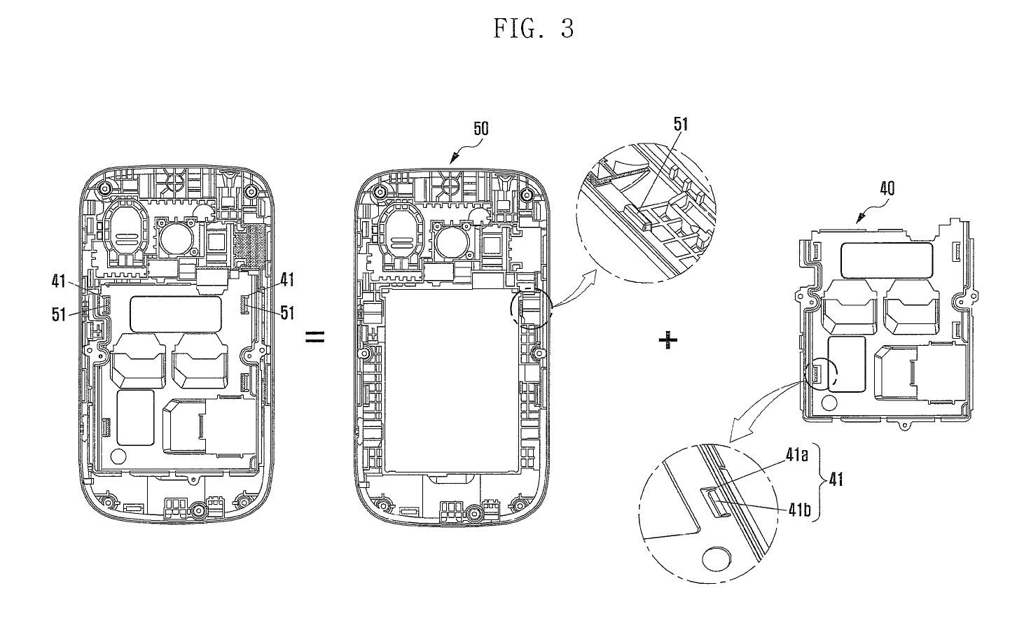

FIG. 1 illustrates an external appearance of an electronic device according to an aspect of the present disclosure, FIG. 2 illustrates an internal configuration of the electronic device illustrated in FIG. 1, and FIG. 3 illustrates a shield-can and a rear case in the internal configuration of the electronic device illustrated in FIG. 1.

Referring to FIGS. 1 to 3, an electronic device 100 according to an aspect of the present disclosure may be formed in a rectangular bar-type. However, the present disclosure is not limited to the aspect illustrated in the drawings. For example, the electronic device according to the present disclosure can be formed in a slide-type, a folder-type, a flip-type, etc. In addition, the electronic device according to the present disclosure can be formed to be flexible.

The electronic device 100 can have an external appearance configured by a front case 10 and a cover case 20.

The front case 10 can include a display unit 130. At the upper end of the display unit 130, a speaker 1, an illuminance sensor 2, and an auxiliary camera 3 can be positioned. The speaker 1 can provide an output function of an audio signal (e.g., telephone conversation voice, MP3 reproduction sound, etc.), the illuminance sensor 2 can provide a function for measuring a brightness of surroundings and the auxiliary camera 3 can provide a video communication function, a self-camera function, etc. Meanwhile, a plurality of keys 4 can be provided at the lower end of the display unit 130. For example, the plurality of keys 4 can include a menu key, a home key and a cancel key. The plurality keys 4 can be formed as button-type physical keys or touch keys.

The cover case 20 can be detachable. For example, the cover case 20 can be a battery cover. The electronic device 100 can include a main camera 5 and a flash 6 which can be positioned at the upper end of the rear face. The main camera 5 can provide an image or video photographing function. When taking a picture, the flash 6 can emit light for a predetermined length of time (e.g., 0.3 sec) depending on a setting.

Meanwhile, the electronic device 100 can include a Printed Circuit Board (PCB) 30, a shield-can 40, and a rear case 50 therein. For example, as illustrated in FIG. 2, the PCB 30, the shield-can, 40 and the rear case 50 can be positioned between the front case 10 and the cover case 20.

The PCB 30 can include a plurality of electronic elements. For example, the PCB 30 can include an Application Processor (AP), a Communication Processor (CP), a memory, a wireless LAN communication module, etc.

The shield-can 40 can be positioned between the printed circuit board 30 and the rear case 50 to protect the electronic elements. The shield-can 40 can be formed of a metal material. For example, the shield-can 40 can be formed of a Steel Use Stainless (SUS) material.

The rear case 50 is positioned on the rear face of the electronic device 100 can be hooked up to the front case 10. In addition, the cover case 20 can be detachably coupled to the rear case 50. The rear case 50 is formed with a battery mounting space 52.

Meanwhile, the rear case 50 and the shield-can 40 according to the aspect of the present disclosure can include a restraint structure configured to prevent the electronic elements from being damaged by external impact. For example, the rear case 50 can include first restraint portions 51 and the shield-can 40 can include second restraint portions 41. As illustrated in FIG. 3, each of the first restraint portions 51 can be formed in a rib structure protruding from the inner surface of the rear case 50. Each of the second restraint portions 41 can be formed by cutting and bending a part of the shield-can 40. For example, each of the second restraint portions 41 can be configured by a hole 41a and a bent portion 41b.

When the shield-can 40 is coupled to the rear case 50, the first restraint portions 51 of the rear case 50 are inserted into the holes 41a of the second restraint portions 41 to be positioned to face the bent portions 41b, respectively. In other words, the shield-can 40 can be restrained to the rear case 50 through the first restraint portions 51 and the second restraint portions 41. In addition, the front case 10, the PCB 30, the shield-can 40, and the rear case 50 of the electronic device 100 can be screw-coupled to each other at least one place. Since the shield-can 40 is restrained to the rear case 50, the front case 10, the PCB 30, the shield-can 40, and the rear case 50 can serve as a single continuous rigid body in the electronic device 100 according to the aspect of the present disclosure. At this time, the shield-can 40 made of a metal can prevent the deformation (e.g., flexure) of the front case 10, the cover case 20, and the rear case 50 which are plastic-molded products due to external impact and disperse the external impact.

In other words, when external impact is applied to the electronic device 100, the external impact can be applied to the shield-can 40 through the rear case 50. At this time, when the shield-can 40 does not absorb nor disperse the external impact sufficiently, the external impact can be transferred to the inside and damage the internal elements of the electronic device 100. However, the electronic device 100 according to the aspect of the present disclosure can absorb or disperse the external impact sufficiently through the restraint structure formed in the shield-can 40 and the rear case 50. As a result, the electronic device 100 according to the aspect of the present disclosure can prevent the internal elements thereof from being damaged by external impact. For example, according to the exemplary embodiment of the present disclosure, the damage of the display unit 130 can be prevented in the electronic device 100 which does not include a bracket configured to protect the display unit 130. In addition, the aspect of the present disclosure can protect a battery cell from external impact and protect the cover case 20 from being released.

Meanwhile, although FIG. 3 illustrates that the electronic device 100 according to the aspect of the present disclosure has four restraint structures and is formed in a rectangular shape which is elongated in the length direction, the present disclosure is not limited thereto. For example, according to the present disclosure, the electronic device 100 can include one or more restraint structures, and the restraint structures can be formed at various positions in at least one of the width direction and the length direction.

Hereinafter, descriptions will be made on restraint structures according to various exemplary embodiments of the present disclosure. In addition, for the convenience of description, different reference numerals indicating respective constituent elements will be used for the respective exemplary embodiments. For example, a first restraint portion according to a first exemplary embodiment will be denoted by reference numeral 151 and a first restraint portion according to a second exemplary embodiment will be denoted by reference numeral 251.

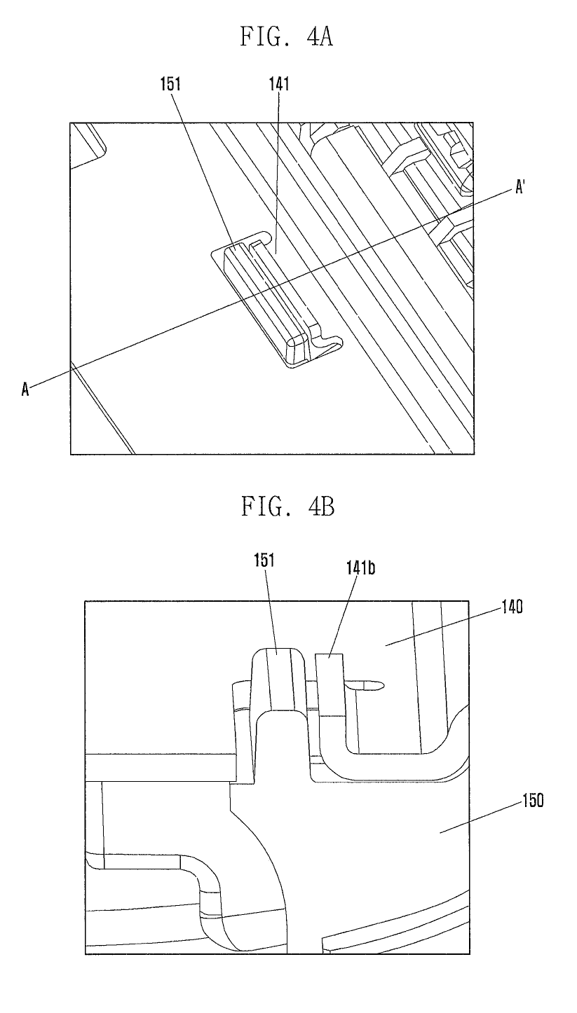

FIG. 4A illustrates the restraint structure according to the first exemplary embodiment of the present disclosure, and FIG. 4B is a cross-section view taken along the line A-A′ shown in FIG. 4A.

Referring to FIGS. 4A and 4B, the first restraint portion 151 of the restraint structure according to the first exemplary embodiment of the present disclosure can be formed at a right angle to a bottom surface. Similarly, a bent portion 141b can be formed at a right angle to the bottom surface in a second restraint portion 141. When impact in the width direction is generated, the first restraint portion 151 can support the second restraint portion 141 to disperse the external impact. Due to this, the first exemplary embodiment of the present disclosure can prevent the external impact from being transferred to the inside. In addition, since the first restraint portion 151 and the bent portion 141b of the second restraint portion 141 are formed at a right angle in relation to each other, the first exemplary embodiment of the present disclosure can allow the shield-can 140 and the rear case 150 to be easily fastened to each other.

Meanwhile, FIGS. 4A and 4B illustrates that the first restraint portion 151 and the second restraint portion 141 are formed in the length direction so as to provide restraint in the width direction (X-axis direction). However, the first exemplary embodiment of the present disclosure is not limited to this. For example, the first restraint portion 151 and the second restraint portion 141 can be formed to extend in the width direction to provide restraint in the length direction (Y-axis direction). Alternatively, the first restraint portion 151 and the second restraint portion 141 can be formed, for example, in a “ [symbol] ” or “+” shape so as to provide restraint both the width and length directions.

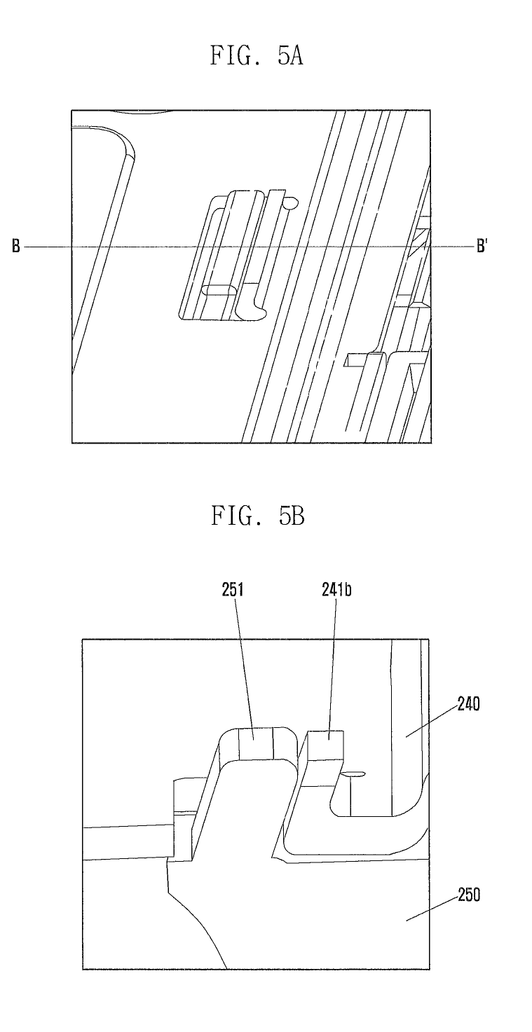

FIG. 5A illustrates a restraint structure according to a second exemplary embodiment of the present disclosure, and FIG. 5B is a cross-section view taken along the line B-B′ shown in FIG. 5A.

Referring to FIGS. 5A and 5B, the restraint structure according to the second exemplary embodiment of the present disclosure can be formed such that a first restraint portion 251 can be formed to be inclined outward in relation to a bottom surface. In addition, the bent portion 241b of the second restraint portion 241 can be formed to be inclined to correspond to the first restraint portion 251. When the first restraint portion 251 and the bent portion 241b of the second restraint portion 241 are inclined outwardly, the second exemplary embodiment of the present disclosure can increase the restraint force between the shield-can 240 and the rear case 250.

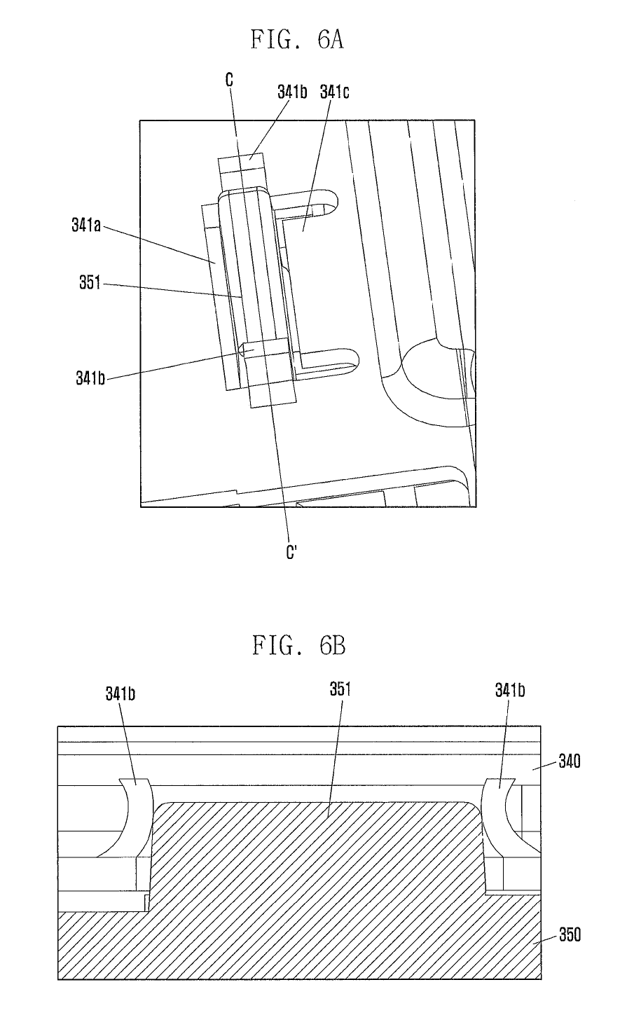

FIG. 6A illustrates a restraint structure according to a third exemplary embodiment of the present disclosure, and FIG. 6B is a cross-section view taken along the line C-C′ shown in FIG. 6A.

Referring to FIGS. 6A and 6B, the restraint structure according to the third exemplary embodiment of the present disclosure can include bent portions 341b of a second restraint portions 341 formed of a resilient material. For example, the second restraint portion 341 according to the third exemplary embodiment of the present disclosure can include elastic bent portions 341b as illustrated in a cross-sectional view of FIG. 6B. At this time, the bent portions 341b can be formed to protrude to the inside of a hole 341a. For example, the distance between the bent portions 341b can be smaller than the width of the second restraint portion 341. Due to this, the first restraint portion 351 can be tight fit (interference fit) between the bent portions 341b of the second restraint portion 341. In this manner, the third exemplary embodiment of the present disclosure described above can increase the restraint force between the shield-can 340 and the rear case 350 using the elastic force of the bent portions 341b. In addition, the second restraint portion 341 can further include a plate portion 341c for the restraint in the width direction (X-axis direction).

Meanwhile, FIGS. 6A and 6B illustrates that the second restraint portions 341b are formed at upper and lower sides of the first restraint portion 351. However, the third exemplary embodiment of the present disclosure is not limited to this. That is, the second restraint portions 341b can be formed at left and right sides of the first restraint portion 351 or top, bottom, left and right sides of the first restraint portion 351.

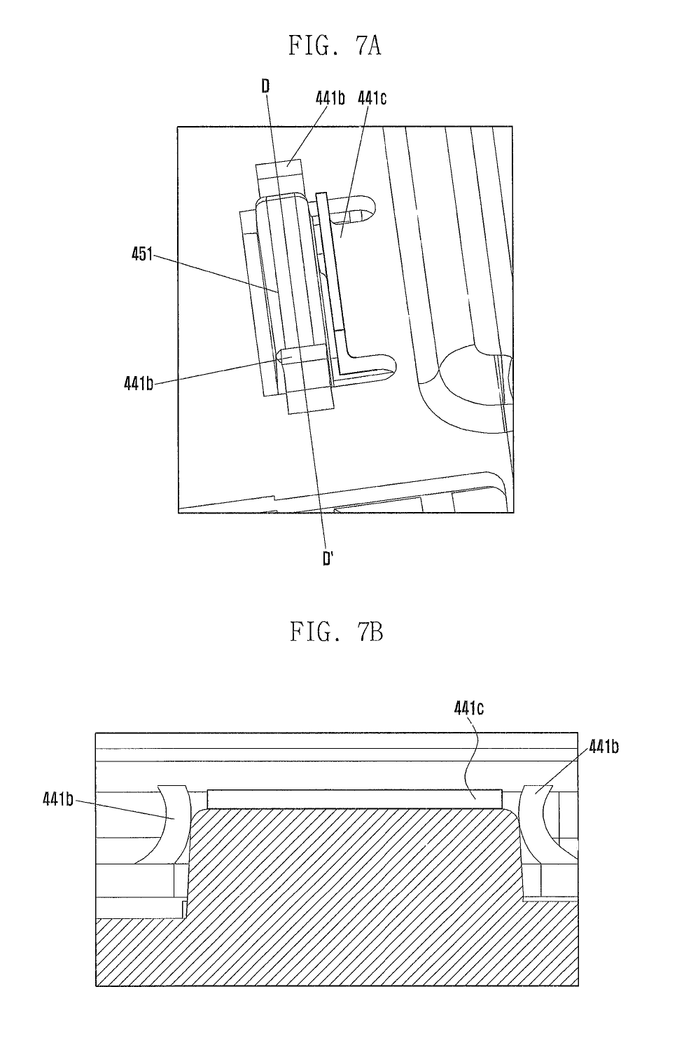

FIG. 7A is a view illustrating a restraint structure according to a fourth exemplary embodiment of the present disclosure, and FIG. 7B is a cross-section view taken along the line D-D′ shown in FIG. 7A.

Referring to FIGS. 7A and 7B, the restraint structure according to the fourth exemplary embodiment of the present disclosure can be formed by combining the first and third exemplary embodiments as described above. For example, the first restraint portion 451 can be formed vertically with reference to the bottom surface. The second restraint portion 441 can include a first bent portion 441b formed to have elasticity at the top side and bottom side and a second bent portion 441c formed vertically. The fourth exemplary embodiment of the present disclosure can minimize the impact in the width direction (X-axis direction) and the impact in the length direction (Y-axis direction).

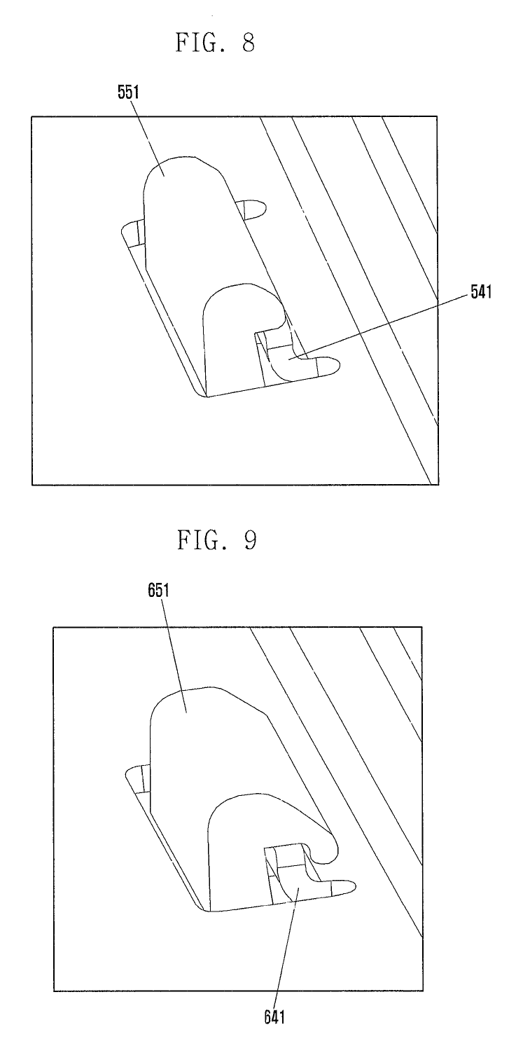

FIG. 8 is a view illustrating a restraint structure according to a fifth exemplary embodiment of the present disclosure.

Referring to FIG. 8, the restraint structure of the fifth exemplary embodiment of the present disclosure can provide restraint in the Z-axis direction. For this purpose, the restraint structure according to the fifth exemplary embodiment of the present disclosure can be formed in a hook shape. For example, a first restraint portion 551 according to the fifth exemplary embodiment of the present disclosure can include a locking step (or stumbling part, stopping part) that covers the upper end surface of the second restraint portion 541. The fifth exemplary embodiment of the present disclosure can provide restraint in the Z-axis direction of the shield-can 540 and the rear case 550.

FIG. 9 is a view illustrating a restraint structure according to a sixth exemplary embodiment of the present disclosure.

Referring to FIG. 9, the restraint structure according to the sixth exemplary embodiment of the present disclosure can be formed in a hook shape similarly to the above-described fifth exemplary embodiment. For example, a first restraint portion 651 according to the sixth exemplary embodiment of the present disclosure can include a locking portion that covers the upper end portion of the second restraint portion 641 and a part of the outer surface. The sixth exemplary embodiment of the present disclosure can prevent the shield-can 640 from being released from the rear case 650 when external impact is applied thereto, thereby increasing restraint force in the Z-axis direction and X-axis direction.

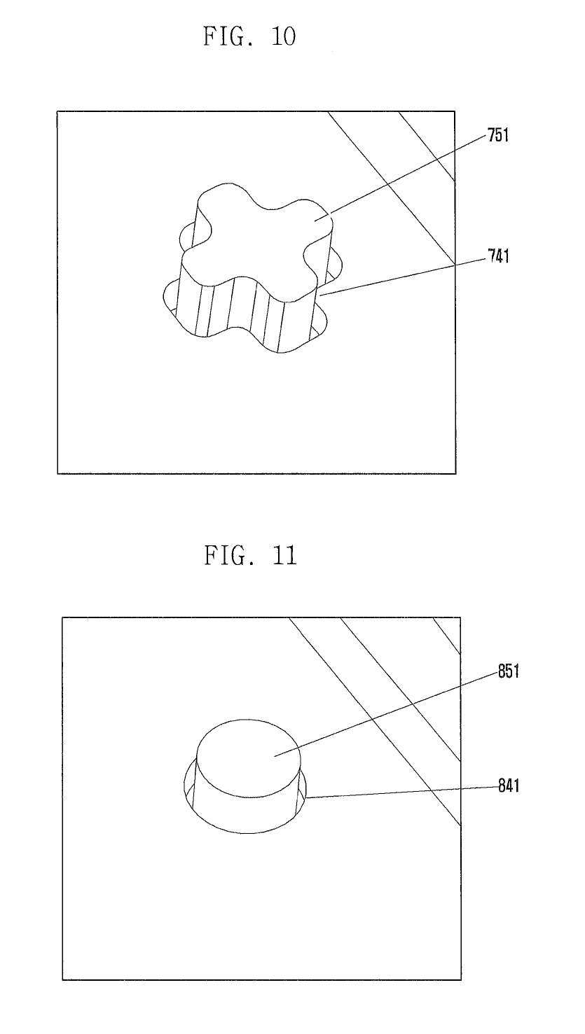

FIG. 10 is a view illustrating a restraint structure according to a seventh exemplary embodiment of the present disclosure.

Referring to FIG. 10, a first restraint portion 751 and a second restraint portion 741 according to the seventh exemplary embodiment of the present disclosure can be formed in a cross (“+”) shape. For example, the first restraint portion 751 can be formed as a column with a cross-shaped cross-section and the second restraint portion 741 can be formed as a hole with a cross-shaped cross-section.

FIG. 11 is a view illustrating a restraint structure according to an eighth exemplary embodiment of the present disclosure.

Referring to FIG. 11, a first restraint portion 851 and a second restraint portion 841 can be formed in a circular shape. For example, the first restraint portion 851 can be formed as a cylindrical column and the second restraint portion 841 can be formed as a cylindrical hole.

As described above, various exemplary embodiments of the present disclosure can strengthen rigidity of an electronic device through restraint structures on a shield-can and a rear case. Accordingly, the electronic devices according to the various exemplary embodiments of the present disclosure can properly disperse external impact to the front case, the printed circuit board, the shield-can, and the rear case. In this manner, the various exemplary embodiments of the present disclosure can strengthen the rigidity of electronic devices to prevent the damage of internal elements of the electronic devices. For example, the various exemplary embodiments of the present disclosure can prevent damage of a display unit by external impact in an electronic device that does not include a bracket for protecting the display unit.

In the foregoing, although electronic device protection devices and electronic devices having the same according to various exemplary embodiments of the present disclosure have been described with reference to the drawings and specific terms have been used merely to help understanding of the present disclosure, the present disclosure is not limited to the exemplary embodiments described above. That is, it is apparent to those skilled in the art that other various embodiments based on the technical idea of the present disclosure can be implemented. Although the present disclosure has been described with an exemplary embodiment, various changes and modifications may be suggested to one skilled in the art. It is intended that the present disclosure encompass such changes and modifications as fall within the scope of the appended claims.

What is claimed is:

1. A protection cover for an electronic device, comprising:
a rear case where a battery is mounted; and
a shield-can made of a metal and coupled to an inner portion of the rear case,
wherein the rear case includes a first restraint portion to restrain the shield-can, and the shield-can includes a second restraint portion corresponding to the first restraint portion.

2. The protection cover of claim 1, wherein the first restraint portion is a rib formed to protrude an inner surface of the rear case, and
the second restraint portion is formed by bending a part of the shield-can.

3. The protection cover of claim 1, wherein the first restraint portion and the second restraint portion are formed vertically.

4. The protection cover of claim 1, wherein the first restraint portion and the second restraint portion are formed to be inclined outwardly.

5. The protection cover of claim 1, wherein the second restraint portion is elastic and is formed such that the first restraint portion is tightly fitted to the second restraint portion.

6. The protection cover of claim 1, wherein the first restraint portion and the second restraint portion are coupled to each type in a hook type.

7. The protection cover of claim 6, wherein the first restraint portion comprises a locking step configured to enclose an upper end surface of the second restraint portion.

8. The protection cover of claim 6, wherein the first restraint portion comprises a locking portion configured to enclose an upper end surface and an outer surface of the second restraint portion.

9. An electronic device, comprising:
a front case where a display unit is mounted;
a rear case coupled to the front case and including at least one first restraint portion;
a printed circuit board positioned between the front case and the rear case; and
a shield-can made of a metal and positioned between the printed circuit hoard and the rear case, the shield-can including at least one second restraint portion corresponding to the at least one first restraint portion.

10. The electronic device of claim 9, wherein the first restraint portion is a rib formed to protrude an inner surface of the rear case, and
the second restraint portion is formed by bending a part of the shield-can.

11. The electronic device of claim 9, wherein the first restraint portion and the second restraint portion are formed vertically.

12. The electronic device of claim 9, wherein the first restraint portion and the second restraint portion are formed to be inclined outwardly.

13. The electronic device of claim 9, wherein the second restraint portion is elastic and is formed such that the first restraint portion is tightly fitted to the second restraint portion.

14. The electronic device of claim 9, wherein the first restraint portion and the second restraint portion are coupled to each type in a hook type.

15. The electronic device of claim 14, wherein the first restraint portion comprises a locking step configured to enclose an upper end surface of the second restraint portion.

16. The electronic device of claim 14, wherein the first restraint portion comprises a locking portion configured to enclose an upper end surface and an outer surface of the second restraint portion.

17. The electronic device of claim 9, wherein the front case, the printed circuit board, the shield-can, and the rear case are screw-coupled to each other in at least one place.

18. The electronic device of claim 9, further comprising:
a cover case detachably coupled with the rear case.

19. The electronic device of claim 9, wherein the first restraint portion is a rectangular shape elongated in a width direction or a length direction.

20. The electronic device of claim 9, wherein the first restraint portion is formed as a cylindrical column or a column with a cross-shaped cross-section, and
the second restraint portion is formed as a cylindrical hole or a hole with a cross-shaped cross-section.
